(19) United States
(12) Patent Application Publication
(10) Pub. No.: US 2022/0241900 A1
(43) Pub. Date: Aug. 4, 2022

(54) SEVERING MACHINE

(71) Applicant: DISCO CORPORATION, Tokyo (JP)

(72) Inventors: Taizo KANEZAKI, Tokyo (JP); Noboru TAKEDA, Tokyo (JP); Keisuke WATANABE, Tokyo (JP); Xiaoming QIU, Tokyo (JP)

(21) Appl. No.: 17/649,009

(22) Filed: Jan. 26, 2022

(30) Foreign Application Priority Data
Jan. 29, 2021 (JP) 2021-013635

(51) Int. Cl. B23K 26/38

(52) U.S. Cl. CPC B23K 26/38

(57) ABSTRACT

A severing machine includes an ingot holding unit configured to hold an SiC ingot with a wafer, which is to be produced, facing up, an ultrasonic generation unit disposed so as to face the SiC ingot held on the ingot holding unit, and configured to generate ultrasonic vibrations, and a liquid supply unit configured to supply liquid between the wafer to be produced and the ultrasonic generation unit. The ultrasonic generation unit includes an ultrasonic transducer, and a case member having a bottom surface formed to have an area equal to or greater than an area to which the ultrasonic vibrations are desired to be applied.

### BACKGROUND OF THE INVENTION

### Field of the Invention

The present invention relates to a severing machine.

### Description of the Related Art

A wafer on which devices are to be formed is manufactured by slicing a semiconductor ingot of a generally cylindrical shape with a wire saw, and polishing front and back surfaces of the resulting sliced wafer.

If wafers are manufactured by the above-mentioned method, however, a large majority (70% to 80% of a volume) of a semiconductor ingot is lost through slicing and polishing, leading a problem of economic disadvantage.

In particular, a silicon carbide (SiC) ingot made of SiC, which has received a growing attention for power device applications in recent years, has high hardness, so that its slicing with a wire saw is hard. There is accordingly a problem that the slicing takes time and results in low productivity.

Therefore, the present assignee and others have proposed a technique that condenses and applies a laser beam of a wavelength having transmissivity through a single-crystal SiC ingot, with a focal point positioned inside the SiC ingot to create cleavage layers along a desired slicing plane, and also a technique that applies ultrasonic vibrations to the SiC ingot in which the cleavage layers have been created, to separate and produce a wafer while using the cleavage layers as severing starting interfaces (see, for example, JP 2016-111143 A and JP 2019-102513 A).

### SUMMARY OF THE INVENTION

To apply ultrasonic vibrations to an SiC ingot, there is a need for ultrasonic vibration applying means having an end face of an area equal to or greater than an area to which the ultrasonic vibrations are desired to be applied. At present, a vibration plate is bonded to an ultrasonic transducer, and accordingly, an end face having a desired area is formed.

However, another problem has become apparent. Specifically, a bonding material that bonds the ultrasonic transducer and the vibration plate together detaches through use over a long period of time, thereby causing variations in characteristics of wafers to be manufactured. Efficient production of wafers can hence no longer be continued.

The present invention therefore has as an object thereof the provision of a severing machine that can efficiently produce a wafer from a semiconductor ingot while suppressing variations in characteristics.

In accordance with an aspect of the present invention, there is provided a severing machine for severing a wafer, which is to be produced, from a semiconductor ingot with cleavage layers formed therein by applying a laser beam of a wavelength, which has transmissivity through the semiconductor ingot, with a focal point of the laser beam positioned at a depth corresponding to a thickness of the wafer to be produced, including an ingot holding unit configured to hold the semiconductor ingot with the wafer, which is to be produced, facing up, an ultrasonic generation unit disposed so as to face the semiconductor ingot held on the ingot holding unit, and configured to generate ultrasonic vibrations, and a liquid supply unit configured to supply liquid between the wafer to be produced and the ultrasonic generation unit. The ultrasonic generation unit includes an ultrasonic transducer, and a case member having a bottom surface formed to have an area equal to or greater than an area to which the ultrasonic vibrations are desired to be applied. The case member is formed integrally with an end face of the ultrasonic transducer.

Preferably, the case member may include any one of stainless steel, titanium, or aluminum.

The present invention provides an advantageous effect that enables efficient production of wafers from a semiconductor ingot while suppressing variations in characteristics.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a plan view of an SiC ingot as a processing object of a severing machine according to a first embodiment;

FIG. 2 is a side view of the SiC ingot illustrated in FIG. 1;

FIG. 3 is a perspective view of a wafer produced by the severing machine according to the first embodiment;

FIG. 4 is a plan view of the SiC ingot illustrated in FIG. 1, with cleavage layers created therein;

FIG. 5 is a cross-sectional view taken along line V-V of FIG. 4;

FIG. 6 is a perspective view illustrating how cleavage layers are created in the SiC ingot illustrated in FIG. 1;

FIG. 7 is a side view illustrating how cleavage layers are created in the SiC ingot illustrated in FIG. 6;

FIG. 8 is a side view illustrating a configuration example of the severing machine according to the first embodiment;

FIG. 9 is a side cross-sectional view of an ultrasonic generation unit of the severing machine illustrated in FIG. 8;

FIG. 10 is a side view illustrating a configuration example of a severing machine according to a second embodiment.

### DETAILED DESCRIPTION OF THE PREFERRED EMBODIMENTS

With reference to the attached drawings, a description will hereinafter be made in detail about embodiments of the present invention. However, the present invention shall not be limited by details that will be described in the subsequent embodiments. The elements of configurations that will hereinafter be described include those readily conceivable to persons skilled in the art and substantially the same ones. Further, the configurations that will hereinafter be described can be combined appropriately. Furthermore, various omissions, replacements and modifications of configurations can be made without departing from the spirit of the present invention.

### First Embodiment

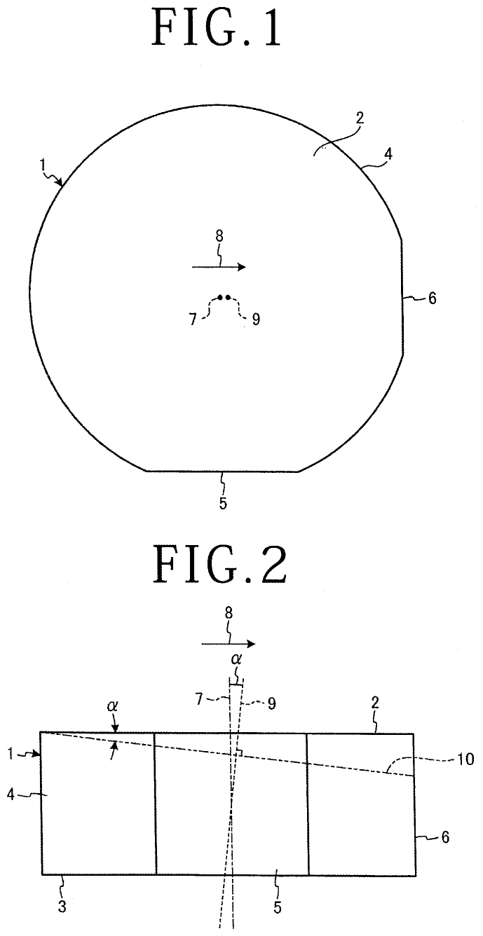

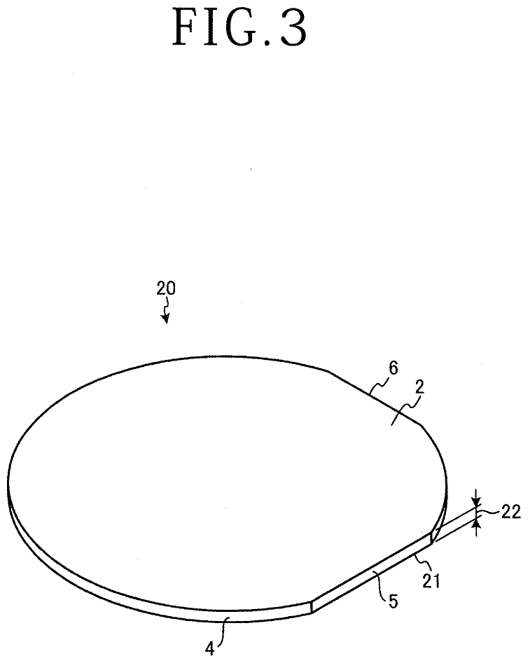

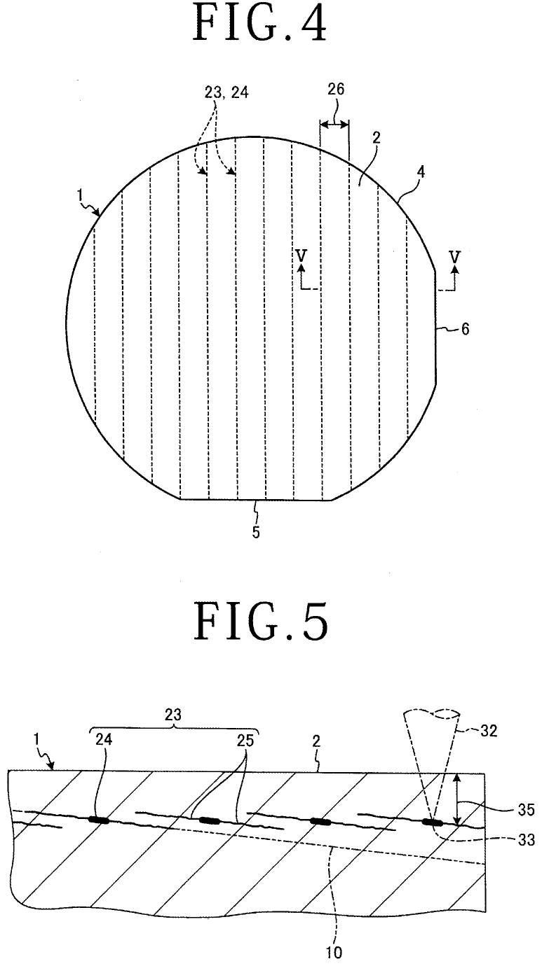

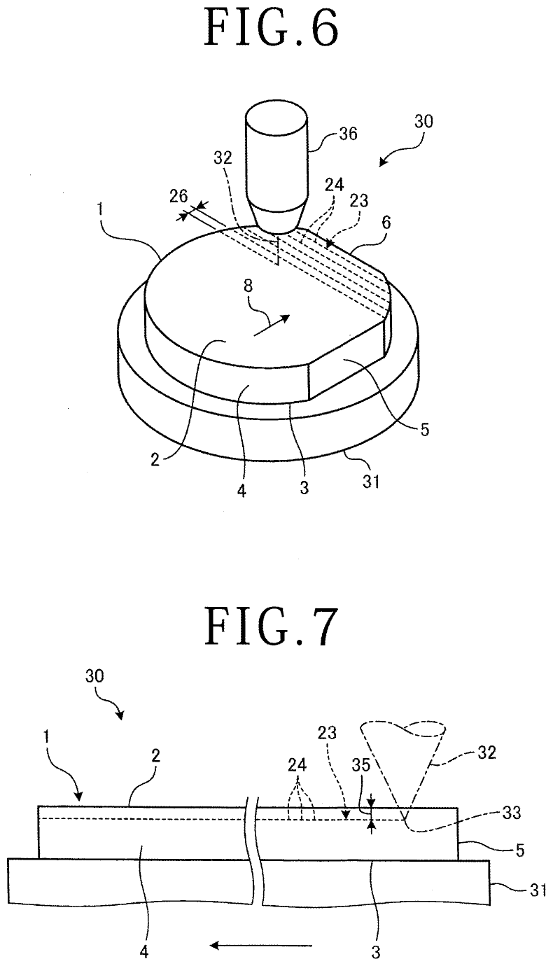

A severing machine according to a first embodiment of the present invention will be described based on FIGS. 1 through 7. First, an SiC ingot as a processing object of the severing machine according to the first embodiment will be described. FIG. 1 is a plan view of the SiC ingot as a processing object of the severing machine according to the first embodiment. FIG. 2 is a side view of the SiC ingot illustrated in FIG. 1. FIG. 3 is a perspective view of a wafer produced by the severing machine according to the first embodiment. FIG. 4 is a plan view of the SiC ingot illustrated in FIG. 1, with cleavage layers created therein. FIG. 5 is a cross-sectional view taken along line V-V of FIG. 4. FIG. 6 is a perspective view illustrating how cleavage layers are created in the SiC ingot illustrated in FIG. 1. FIG. 7 is a side view illustrating how cleavage layers are formed in the SiC ingot illustrated in FIG. 6.

(SiC Ingot)

In the first embodiment, an SiC ingot 1 illustrated in FIGS. 1 and 2 is made of SiC, and as a whole, is formed in a cylindrical shape. In the first embodiment, the SiC ingot 1 is a hexagonal single-crystal SiC ingot.

As illustrated in FIGS. 1 and 2, the SiC ingot 1 has a first surface 2 which is a circular end face, a circular second surface 3 on a side of a back face opposite to the first surface 2, and a peripheral surface 4 extending to an outer peripheral edge of the first surface 2 and an outer peripheral edge of the second surface 3. On the peripheral surface 4, the SiC ingot 1 also has a first orientation flat 5, and a second orientation flat 6 that intersects the first orientation flat 5 at right angles. The first orientation flat 5 and second orientation flat 6 indicate respective crystal orientations. The first orientation flat 5 has a length greater than the second orientation flat 6.

The SiC ingot 1 also has a c-axis 9, and a c-plane 10 that intersects the c-axis 9 at right angles. The c-axis 9 is inclined, at an off-angle α relative to a normal 7 to the first surface 2, in an incline direction 8 toward the second orientation flat 6. The c-plane 10 is also inclined at the same off-angle α relative to the first surface 2 of the SiC ingot 1. The incline direction 8 of the c-axis 9 from the normal 7 is orthogonal to the direction of extension of the second orientation flat 6, and is parallel to the first orientation flat 5. On the molecular level of the SiC ingot 1, an innumerable number of c-planes 10 is set in the SiC ingot 1. In the first embodiment, the off-angle α is set at 1°, 4°, or 6°. In the present invention, however, the SiC ingot 1 can be produced by setting the off-angle α as desired, for example, in a range of 1° to 6°.

After the first surface 2 has been subjected to grinding processing by a grinding machine, the SiC ingot 1 is then subjected to polishing processing by a polishing machine, whereby the first surface 2 is formed into a mirror surface. The SiC ingot 1 is severed at a portion thereof on a side of the first surface 2, and the severed portion is then manufactured into a wafer 20 illustrated in FIG. 3.

The wafer 20 illustrated in FIG. 3 is manufactured by severing the portion of the SiC ingot 1, and then applying grinding processing, polishing processing, and the like to a surface 21 severed from the SiC ingot 1. After severed from the SiC ingot 1 and subjected to the grinding processing, polishing processing, and the like, devices are formed on a surface of the wafer 20. In the first embodiment, the devices are metal-oxide semiconductor field-effect transistors (MOSFET), micro electro mechanical systems (MEMS), or Schottky barrier diodes (SBD), although the devices are not limited to MOSFET, MEMS, or SBD in the present invention. In the wafer 20, the same parts as those of the SiC ingot 1 are identified by the same reference numerals, and their description is omitted.

After creation of cleavage layers 23, which are illustrated in FIGS. 4 and 5, in the SiC ingot 1 illustrated in FIGS. 1 and 2, a portion of the SiC ingot 1, specifically the wafer 20 to be produced is severed and separated by use of the cleavage layer 23 as severing starting interfaces. The SiC ingot 1 is held on a side of the second surface 3 under suction on a holding table 31 of a laser processing machine 30 (see FIGS. 6 and 7), and the cleavage layers 23 are then created by the laser processing machine 30. With a focal point 33 of a pulsed laser beam 32 (see FIG. 7) of a wavelength, which has transmissivity through the SiC ingot 1, being positioned at a depth 35 (see FIGS. 5 and 7) corresponding to a thickness 22 of the wafer 20 to be produced from the first surface 2 of the SiC ingot 1, the laser processing machine 30 applies the pulsed laser beam 32 along the second orientation flat 6 to create the cleavage layers 23 inside the SiC ingot 1.

When the pulsed laser beam 32 of the wavelength having transmissivity through the SiC ingot 1 is applied, SiC dissociates into silicon (Si) and carbon (C) by the application of the pulsed laser beam 32 as illustrated in FIG. 5, the pulsed laser beam 32 applied next is absorbed in the C formed previously, and SiC dissociates into Si and C in a chain manner. As a consequence, modified layers 24 are formed along the second orientation flat 6 inside the SiC ingot 1, and at the same time, cracks 25 are formed extending from the modified portions 24 along the c-plane 10. The cleavage layers 23, which include the modified portions 24 and the cracks 25 formed from the modified portions 24 along the c-plane 10, are therefore created inside the SiC ingot 1 when the pulsed laser beam 32 of the wavelength having transmissivity through the SiC ingot 1 is applied.

For the creation of the cleavage layers 23, the laser processing machine 30 applies the laser beam 32 over an entire length in a direction parallel to the second orientation flat 6 of the SiC ingot 1, and then subjects the SiC ingot 1 and a laser beam application unit 36, which applies the laser beam 32, to relative index feeding along the first orientation flat 5.

With the focal point 33 again positioned at the desired depth from the first surface 2, the laser processing machine 30 applies the pulsed laser beam 32 to the SiC ingot 1 along the second orientation flat 6, whereby cleavage layers 23 are created inside the SiC ingot 1. The laser processing machine 30 repeats the operation of applying the laser beam 32 along the second orientation flat 6, and the operation of subjecting the SiC ingot 1 and the laser beam application unit 36 to relative index feeding along the first orientation flat 5.

As a consequence, at every move distance 26 of the index feeding, cleavage layers 23 are created at the depth 35 which corresponds to the thickness 22 of the wafer 20, from the first surface 2. Each cleavage layer 23 includes a modified portion 24 in which SiC has dissociated into Si and C, and cracks 25, and has a lower strength than the portions other than the cleavage layers 23. In the SiC ingot 1, the cleavage layers 23 are created at the depth 35 which corresponds to the thickness 22 of the wafer 20, from the first surface 2 at every move distance 26 of the index feeding over an entire length in a direction parallel to the first orientation flat 5.

(Severing Machine)

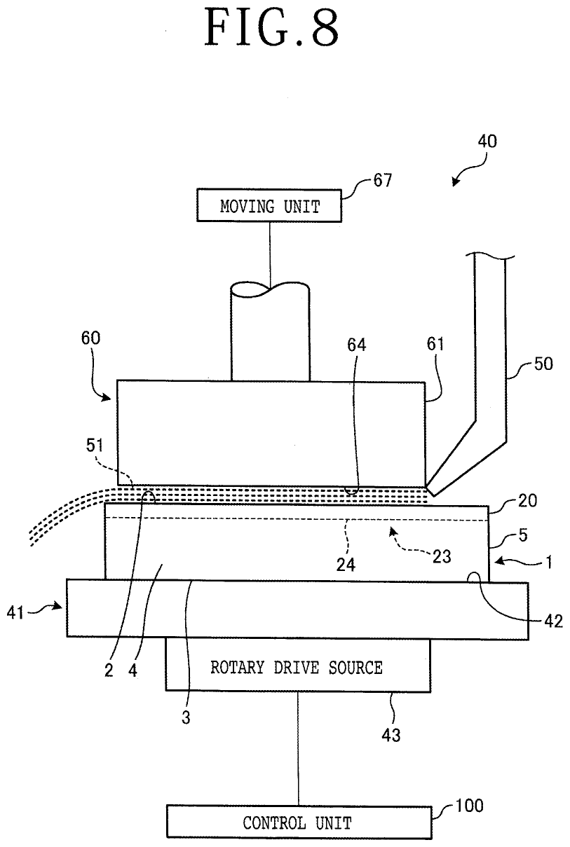

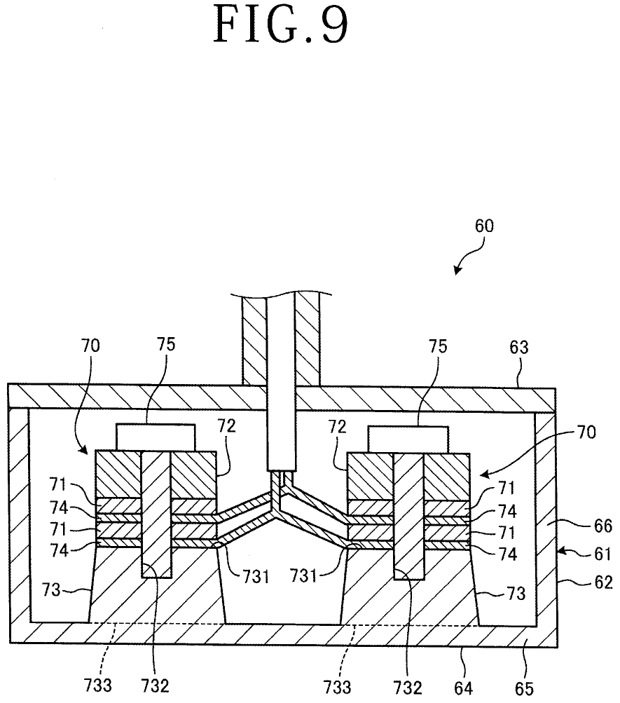

A description will next be made of a severing machine. FIG. 8 is a side view illustrating a configuration example of the severing machine according to the first embodiment. FIG. 9 is a side cross-sectional view of an ultrasonic generation unit of the severing machine illustrated in FIG. 8. The severing machine 40 according to the first embodiment serves to sever the wafer 20, which is illustrated in FIG. 4 and is to be produced, from the SiC ingot 1 in which the cleavage layers 23 illustrated in FIGS. 4 and 5 have been formed.

The severing machine 40 serves to sever the wafer 20, which is to be produced, from the SiC ingot 1 in which the cleavage layers 23 have been formed by applying the laser beam 32 of the wavelength, which has transmissivity through the SiC ingot 1, with the focal point 33 of the laser beam 32 positioned at the depth 35 corresponding to the thickness 22 of the wafer 20 to be produced. As illustrated in FIG. 8, the severing machine 40 includes an ingot holding unit 41, a liquid supply unit 50, an ultrasonic generation unit 60, and a control unit 100.

The ingot holding unit 41 serves to hold the SiC ingot 1 with the wafer 20, which is to be produced, facing up. The ingot holding unit 41 is formed in a thick disc shape, and has an upper surface as a holding surface 42 that lies parallel to a horizontal direction. The SiC ingot 1 is placed at the second surface 3 thereof on the holding surface 42, and is held there with the first surface 2 facing up. In the first embodiment, the ingot holding unit 41 holds the second surface 3 of the SiC ingot 1 under suction on the holding surface 42 (in other words, vacuum-fixes). The ingot holding unit 41, with the SiC ingot 1 held on the holding surface 42, is rotated about an axis of rotation by a rotary drive source 43.

The liquid supply unit 50 serves to supply liquid 51 (see FIG. 8) between the wafer 20 to be produced and the ultrasonic generation unit 60. The liquid supply unit 50 is a tube that supplies from a lower end thereof the liquid 51 supplied from a liquid supply source, and in the first embodiment, supplies the liquid 51 onto the first surface 2 of the SiC ingot 1 held on the ingot holding unit 41. In the first embodiment, the liquid supply unit 50 is disposed movably up and down by an unillustrated lift mechanism.

The ultrasonic generation unit 60 is arranged so as to face the SiC ingot 1 held on the ingot holding unit 41, and serves to generate ultrasonic vibrations. As illustrated in FIG. 9, the ultrasonic generation unit 60 includes a case member 61, and ultrasonic transducers 70.

The case member 61 includes a box-shaped case main body 62 with an opening formed in an upper portion thereof, and a plate-shaped lid 63. The case main body 62 is made of metal, and integrally includes a disc-shaped bottom surface portion 65 and a cylindrical portion 66. The bottom surface portion 65 has a bottom surface 64 facing the first surface 2 of the SiC ingot 1 held on the ingot holding unit 41, and the cylindrical portion 66 is disposed upright from an outer peripheral edge of the bottom surface portion 65. In the present invention, the case member 61 may use the ultrasonic transducers 70, for example, as many as six, and the bottom surface portion 65 thereof may be formed in an oval shape. If the bottom surface portion 65 of the case member 61 is formed in a square shape or rectangular shape in the present invention, the distance from each ultrasonic transducer 70 to the case member 61 varies depending on its position, thereby possibly affecting the cleavability. It is therefore preferred to form the bottom surface portion 65 in a disc shape or an oval shape such that the distances from the respective ultrasonic transducers 70 to the bottom surface portion 65 of the case member 61 are made as equal as possible.

The bottom surface 64 of the bottom surface portion 65 of the case main body 62 is formed to have an area equal to or greater than the area of the first surface 2 of the SiC ingot 1 to which first surface 2 the ultrasonic generation unit 60 is desired to apply ultrasonic vibrations. In other words, the case member 61 has the bottom surface 64 having an area equal to or greater than the area of the first surface 2 of the SiC ingot 1 to which first surface 2 the ultrasonic generation unit 60 is desired to apply ultrasonic vibrations.

In the present invention, the expression “having an area equal to or greater than the area of the first surface 2 of the SiC ingot 1 to which first surface 2 the ultrasonic generation unit 60 is desired to apply ultrasonic vibrations” preferably indicates that the area of the bottom surface 64 of the case main body 62 is as large as 50% or greater and 150% or smaller of the area of the first surface 2 of the SiC ingot 1 held on the ingot holding unit 41, to which first surface 2 ultrasonic vibrations are desired to be applied.

Even if the area of the bottom surface 64 is smaller than 50% of the area of the first surface 2, the wafer 20 to be produced can still be severed from the SiC ingot 1 by reciprocating the ultrasonic generation unit 60 along the second orientation flat 6. With such a small area, however, a long period of time is required until the wafer 20 can be severed from the SiC ingot 1. If the area of the bottom surface 64 exceeds 150% of the area of the first surface 2, on the other hand, the severing machine 40 undesirably increases in overall size, and a difficulty arises in allowing the liquid supply unit 50 to supply the liquid 51 between the wafer 20, which is to be produced, of the SiC ingot 1 and the bottom surface 64 of the ultrasonic generation unit 60. In the first embodiment, the area of the bottom surface 64 is 80% of the area of the first surface 2.

The lid 63 is formed in a disc shape having an outer diameter equal to that of the bottom surface 64. The lid 63 is fixed at an outer peripheral edge thereof on an outer peripheral edge of the cylindrical portion 66, and therefore closes the opening of the case main body 62.

The ultrasonic transducers 70 generate ultrasonic vibrations. These ultrasonic transducers 70 are accommodated in the case member 61, are arranged at intervals, and are fixed on the bottom surface portion 65 of the case main body 62.

Each ultrasonic transducer 70 includes two annular piezoelectric elements 71, a first metal block 72 of a cylindrical shape, a second metal block 73, and a fixing bolt 75.

In the ultrasonic transducer 70, the two piezoelectric elements 71 are stacked together in the direction of a central axis of the ultrasonic transducer 70. The piezoelectric elements 71 are made of lead titanate zirconate, which expands and contacts in a thickness direction when an alternate current power is applied.

The first metal block 72 is made of metal, and is stacked with one of the piezoelectric elements 71. The second metal block 73 is made of metal, and is stacked with the other piezoelectric element 71. The second metal block 73 is formed in a truncated conical shape with an external diameter increasing with the distance from the other piezoelectric element 71. The second metal block 73 is stacked at an end face 731 thereof with the other piezoelectric element 71, and a threaded hole 732 is formed in the end face 731. The bolt 75 is disposed in threaded engagement with the threaded hole 732.

The ultrasonic transducer 70 is assembled as will be described hereinafter. The bolt 75 is inserted through the first metal block 72, the one piezoelectric element 71, and the other piezoelectric element 71 in this order, and is brought into threaded engagement with the threaded hole 732 of the second metal block 73. Upon threaded engagement with the threaded hole 732, the bolt 75 fixes the first metal block 72, the one piezoelectric element 71, the other piezoelectric element 71, and the second metal block 73 together.

In the first embodiment, the first metal block 72, the one piezoelectric element 71, the other piezoelectric element 71, and the second metal block 73, all of which are fixed together by the bolt 75, are arranged at positions where they are coaxial to one another. Further, each ultrasonic transducer 70 also includes two electrodes 74, one disposed between the piezoelectric elements 71, and the other between the other piezoelectric element 71 and the second metal block 73, so that the alternate current power is applied to the piezoelectric elements 71. The electrodes 74 are electrically connected to an unillustrated alternate current power source that supplies the alternate current power. When the alternate current power is applied to the electrodes 74 and the piezoelectric elements 71 expand and contract, the ultrasonic generation unit 60 vibrates (undergoes generally-called ultrasonic vibrations), in its entirety, specifically, in particular, at the bottom surface 64, at a frequency of 20 kHz or higher and 200 kHz or lower and an amplitude of several micrometers to several tens micrometers.

In the first embodiment, the case member 61 and the metal blocks 72 and 73 of each ultrasonic generation unit 60 are made of the same metal material. When the piezoelectric elements 71 expand and contact to undergo ultrasonic vibrations, a material of smaller specific gravity allows the ultrasonic generation unit 60 to vibrate easier. The case member 61 and the metal blocks 72 and 73 are therefore made of the same metal material of small specific gravity.

In the first embodiment, the metal that makes up the case member 61 and the metal blocks 72 and 73 is stainless steel, titanium alloy, or aluminum alloy. Therefore, the metal that makes up the case member 61 and the metal blocks 72 and 73 includes any one of stainless steel, titanium, or aluminum. If the metal that makes up the case member 61 and the metal blocks 72 and 73 is aluminum alloy, the aluminum alloy may desirably be extra super duralumin (specified by Japanese Industrial Standards (JIS) A7075) to suppress cavitation damage.

In the present invention, the metal that makes up the case member 61 and the metal blocks 72 and 73 may desirably be stainless steel having a greater specific gravity than aluminum alloy such as extra super duralumin, because an increase in weight reduces load-dependent variations in characteristics and hence facilitates tracking control of resonant frequency by the alternate current power source. In the first embodiment, the ultrasonic generation unit 60 is 1.4 kg if aluminum alloy is used, while stainless steel of the same external shape is 1.8 kg.

In the first embodiment, the bottom surface portion 65 of the case member 61 is integrally formed with end faces 733 of the second metal blocks 73 of the respective ultrasonic transducers 70. The end faces 733 are located on sides remote from the adjacent piezoelectric elements 71, and are indicated by dotted lines in FIG. 9. That is, in the first embodiment, the bottom surface portion 65 of the case member 61 and the second metal blocks 73 are integral with each other in the ultrasonic generation unit 60. The bottom surface portion 65 of the case member 61 and the second metal blocks 73 are produced as an integral element by applying contour grinding to a metal lump.

Also, in the first embodiment, by a moving unit 67, the ultrasonic generation unit 60 is moved along the holding surface 42 of the ingot holding unit 41, and is also moved up and down along a direction that intersects (in the first embodiment, is orthogonal to) the holding surface 42.

The control unit 100 serves to control the above-mentioned elements of the severing machine 40, and to make the severing machine 40 perform processing operation on the SiC ingot 1. The control unit 100 is a computer, which includes an arithmetic logic unit having a microprocessor such as a central processing unit (CPU), a storage device having a memory such as a read only memory (ROM) or a random access memory (RAM), and an input/output interface device. The arithmetic logic unit of the control unit 100 performs arithmetic logic processing in accordance with a computer program stored in the storage device, and outputs control signals to the above-mentioned elements of the severing machine 40 via the input/output interface device to control the severing machine 40.

The control unit 100 is connected to an unillustrated display unit and an unillustrated input unit. The display unit is configured by a liquid crystal display device or the like, which displays statuses, images, and/or the like of processing operation. The input unit is used when an operator registers information regarding processing details and the like. The input unit is configured by at least one of a touch panel disposed in the display unit, and an external input device such as a keyboard.

When the SiC ingot 1 with the cleavage layers 23 created therein is placed at the second surface 3 thereof on the holding surface 42 of the ingot holding unit 41, the control unit 100 receives information about processing details via the input unit and stores it in the storage device, and the control unit 100 receives a processing start instruction from the operator, the severing machine 40 according to the first embodiment starts processing operation.

As the liquid supply unit 50 and the ultrasonic generation unit 60 are integrated together, the severing machine 40, in the processing operation, lowers the liquid supply unit 50 and the ultrasonic generation unit 60 close to the first surface 2 of the SiC ingot 1 held on the ingot holding unit 41. The severing machine 40 supplies the liquid 51 from the liquid supply unit 50 to the first surface 2 of the SiC ingot 1 held on the ingot holding unit 41, whereby the bottom surface 64 of the case member 61 is immersed in the liquid 51 over the first surface 2 of the SiC ingot 1.

While rotating the ingot holding unit 41 about the axis of rotation by the rotary drive source 43 and reciprocating the ultrasonic generation unit 60 along the holding surface 42, the severing machine 40 applies the alternate current power for a predetermined period of time to the piezoelectric elements 71 of each ultrasonic transducer 70 of the ultrasonic generation unit 60 to ultrasonically vibrate the bottom surface 64. The severing machine 40 allows the ultrasonic vibrations of the bottom surface 64 to propagate to the first surface 2 of the SiC ingot 1 via the liquid 51, so that the ultrasonic vibrations are applied to the first surface 2 of the SiC ingot 1. Then, the ultrasonic vibrations from the ultrasonic generation unit 60 cause excitation of the cleavage layers 23, thereby severing the SiC ingot 1 while using the cleavage layers 23 as severing starting interfaces. As a consequence, the wafer 20 to be produced is separated from the SiC ingot 1. After the alternate current power has been applied for the predetermined period of time to the piezoelectric elements 71 of each ultrasonic transducer 70 of the ultrasonic generation unit 60, the severing machine 40 ends the processing operation. As an alternative, the severing machine 40 may also be configured to end the processing operation when the separation of the severed wafer 20 from the SiC ingot 1 is detected.

Subsequent to the separation from the SiC ingot 1, the wafer 20 to be produced is sucked by an unillustrated suction mechanism, and therefore is peeled off from the SiC ingot 1. Grinding machining, polishing machining, and the like are then applied to the severed surface 21 (see FIG. 3).

As has been described above, the severing machine 40 according to the first embodiment includes the ultrasonic generation unit 60 in which the second metal blocks 73 of the ultrasonic transducers 70 and the bottom surface portion 65 of the case member 61, the bottom surface portion 65 serving to function as a vibration plate, are integrated together. It is therefore possible to suppress variations in the characteristics (frequency, amplitude) of the ultrasonic transducers 70 without detachment of a bonding material or the like that fixes the ultrasonic transducers 70 and the bottom surface portion 65 together. As a result, the severing machine 40 according to the first embodiment provides an advantageous effect that the wafer 20 can be efficiently produced from the SiC ingot 1 while suppressing variations in the characteristics of the ultrasonic transducers 70.

In addition, the severing machine 40 according to the first embodiment is substantially free of variations in the characteristics of the ultrasonic transducers 70 through time, so that variations of load during application of ultrasonic vibrations can also be suppressed, the ultrasonic transducers 70 can be stably driven with a phase difference of 0%, and hence the power efficiency is improved (for example, improved to approximately 100% as opposed to 50% in the past).

### Second Embodiment

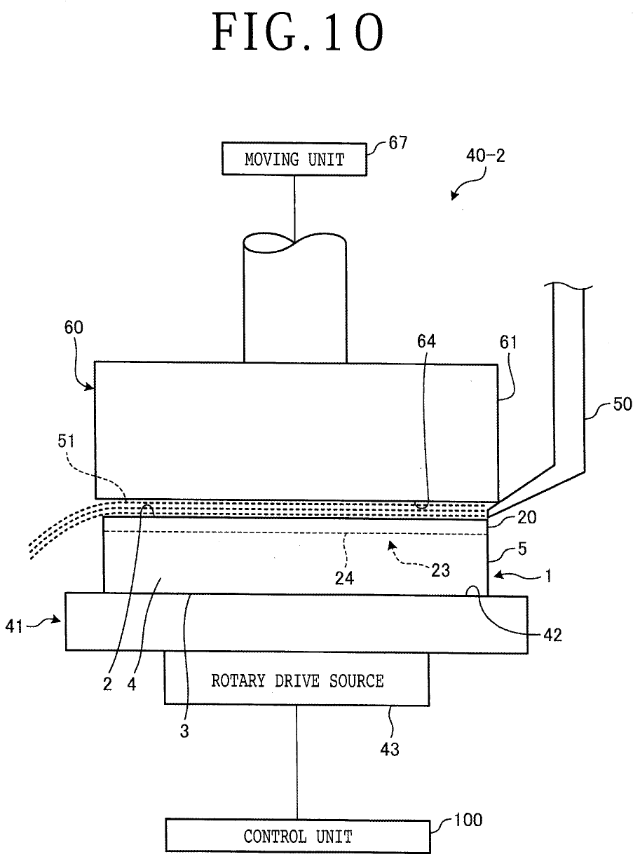

A severing machine according to a second embodiment of the present invention will be described based on FIG. 10. FIG. 10 is a side view illustrating a configuration example of the severing machine according to the second embodiment. In FIG. 10, the same parts as those of the first embodiment are identified by the same reference numerals, and their description is omitted.

A severing machine 40-2 according to the second embodiment as illustrated in FIG. 10 is the same as the severing machine 40 according to the first embodiment except that the area of the bottom surface 64 is 120% of the area of the first surface 2.

Also referring to FIG. 9, the severing machine 40-2 according to the second embodiment includes the ultrasonic generation unit 60 in which the second metal blocks 73 of the ultrasonic transducers 70 and the bottom surface portion 65 of the case member 61, the bottom surface portion 65 serving to function as the vibration plate, are integrated together. Similar to the first embodiment, the severing machine 40-2 according to the second embodiment also provides the advantageous effect that the wafer 20 can be efficiently produced from the SiC ingot 1 while suppressing variations in the characteristics of the ultrasonic transducers 70.

The inventor of the present invention next verified the above-mentioned advantageous effects of the severing machines 40 and 40-2 according to the first and second embodiments by ascertaining the statuses of occurrence of any detachment between the second metal blocks 73 and the bottom surface portion 65 of the case member 61 when wafers 20 were separated from SiC ingots 1 of the same type using a severing machine of a comparative example, an invention severing machine A and an invention severing machine B separately. The results are presented in Table 1.

TABLE 1

| Severing machine | Occurrence of detachment |
|---|---|
| Invention machine A | None |
| Invention machine B | None |
| Comparative machine | Occurred |

In the comparative severing machine of Table 1, the second metal blocks 73 of the ultrasonic transducers 70 and the bottom surface portion 65 of the case member 61 in the severing machine 40 according to the first embodiment were formed as discrete members, and those discrete members were then fixed together with a bonding material.

The invention severing machine A of Table 1 was the severing machine 40 according to the first embodiment, and the invention severing machine B of Table 1 was the severing machine 40-2 according to the second embodiment.

Table 1 presents the statuses of occurrence of any detachment between the second metal blocks 73 and the bottom surface portion 65 of the case member 61 when the wafers 20 were produced from the SiC ingots 1 having an outer diameter of four inches, in the comparative severing machine, the invention severing machine A, and the invention severing machine B separately. Among the comparative severing machine, the invention severing machine A, and the invention severing machine B, the alternate current power applied to the piezoelectric elements 71 was set equal in frequency, current value, and application time.

According to Table 1, with the comparative severing machine, detachment occurred after the ultrasonic transducers 70 were driven for 1,000 hours. In contrast to the comparative severing machine as described above, with the invention severing machine A and the invention severing machine B, no detachment occurred even after the ultrasonic transducers 70 were driven for 1,000 hours.

According to Table 1, it has therefore become clear that the inclusion of the ultrasonic generation unit 60 in which the second metal blocks 73 of the ultrasonic transducers 70 and the bottom surface portion 65 of the case member 61, the bottom surface portion 65 serving to function as a vibration plate, are integrated together can suppress the occurrence of detachment between the ultrasonic transducers 70 and the bottom surface portion 65.

It is to be noted that the present invention should not be limited to the embodiments described above. Described specifically, the present invention can be practiced with changes or modifications to such extent as not departing from the spirit of the present invention. For example, the severing machines 40 and 40-2 may have peeling means that peels off the wafer 20 separated from the SiC ingot 1 by the application of ultrasonic vibrations, in other words, means that sucks, holds, and transfers the wafer 20.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A severing machine for severing a wafer, which is to be produced, from a semiconductor ingot with cleavage layers formed therein by applying a laser beam of a wavelength, which has transmissivity through the semiconductor ingot, with a focal point of the laser beam positioned at a depth corresponding to a thickness of the wafer to be produced, comprising:
an ingot holding unit configured to hold the semiconductor ingot with the wafer, which is to be produced, facing up;
an ultrasonic generation unit disposed so as to face the semiconductor ingot held on the ingot holding unit, and configured to generate ultrasonic vibrations; and
a liquid supply unit configured to supply liquid between the wafer to be produced and the ultrasonic generation unit,
wherein the ultrasonic generation unit includes
an ultrasonic transducer, and
a case member having a bottom surface formed to have an area equal to or greater than an area to which the ultrasonic vibrations are desired to be applied, and
the case member is formed integrally with an end face of the ultrasonic transducer.

2. The severing machine according to claim 1,
wherein the case member includes any one of stainless steel, titanium, or aluminum.
